(19) United States
(12) Patent Application Publication
(10) Pub. No.: US 2010/0277189 A1
(43) Pub. Date: Nov. 4, 2010

(54) CURRENT MEASURING SYSTEM AND METHOD FOR MEASURING CURRENT

(76) Inventor: SHIH-CHIEH KING, Xindian City (TW)

Correspondence Address: LIN & ASSOCIATES INTELLECTUAL PROPERTY, INC., P.O. BOX 2339, SARATOGA, CA, 95070-0339, US

(21) Appl. No.: 12/772,148

(22) Filed: Apr. 30, 2010

(30) Foreign Application Priority Data
May 1, 2009 (TW) 098114643

(51) Int. Cl. G01R 27/08

(52) U.S. Cl. 324/705

(57) ABSTRACT

A current measuring system and a method thereof adapted for measuring a current of a current driving module/circuit are provided. When the current measuring system and the method thereof are used for measuring the current, the current measuring system is not required to be well matched with the current driving module/circuit, and the component ratio or the ideal current ratio of the current driving module/circuit would not be concerned. Further, in the IC layout of the current measuring system, the current measuring system is not required to be distributed adjacent to the current driving module/circuit, or they can be configured in same or different IC chips. When the current measuring system and the method thereof are used for measuring the current flowing through the current driving module/circuit, the current can be measured by determining an output point voltage or a difference between an external voltage and the output point voltage.

### BACKGROUND OF THE INVENTION

1. Field of the Invention

The present invention relates generally to a current measuring system and a method for measuring a current flowing through a module or a circuit, and more particularly, to a current measuring system and a method adapted for measuring a current flowing through a current driving module/circuit.

2. The Prior Arts

Currently, with respect to a circuit/module/system adapted for measuring a current driving module/circuit, a measuring circuit is required and must be well matched with the current driving module/circuit being measured thereby. Further, the measuring circuit and the current driving module/circuit are usually preferred to be adjacently arranged in the IC layout. The measuring circuit and the current driving module/circuit are also preferred to have similar appearances, and be arranged in a same orientation. Further, the component ratio between the measuring circuit and the current driving module/circuit shall be restricted by the specification of the IC layout.

Generally, the measuring circuit (or module, or system) is adapted for measuring a current by obtaining an ideal current ratio in accordance with the component ratio between the measuring circuit and the current driving module/circuit and then obtaining the current flowing through the current driving module/circuit by measuring a voltage drop.

However, any undesired variation during the IC processing may cause a deviation of the absolute value of the resistance of the measuring circuit, and further in view of that the measuring circuit is very difficult to be well matched with current driving module/circuit, the error of the voltage drop measured by the measuring circuit may exceed 10%. Further, any undesired variation during the IC processing may also cause a deviation of the component ratio between the measuring circuit and the current driving module/circuit or the ideal current ratio, so as to further affect the measurement of the operation current of the current driving module/circuit.

As such, it is desired to develop a current measuring system and a method thereof adapted for measuring a current of a current driving module/circuit. In accordance with the current measuring system and the method, in measuring the current of the current driving module/circuit, there is no need to consider whether or not the measuring system is well matched with the current driving module/circuit, and there is no need to consider the component ratio and the ideal current ratio. Further, in the IC layout, the measuring system is not required to be distributed adjacent to the current driving circuit and configured by a same IC processing. On the contrary, they can be configured in different IC chips.

### SUMMARY OF THE INVENTION

Accordingly, a primary objective of the present invention is to provide a current measuring system and a method thereof adapted for measuring a current of a current driving module/circuit. When the current measuring system and the method thereof are used for measuring the current, the current measuring system is not required to be well matched with the current driving module/circuit.

Another objective of the present invention is to provide a current measuring system and a method thereof adapted for measuring a current of a current driving module/circuit. When the current measuring system and the method thereof are used for measuring the current flowing through the current driving module/circuit, the current can be measured by determining an output point voltage or a difference between an external voltage and the output point voltage.

A further objective of the present invention is to provide current measuring system and a method thereof adapted for measuring a current of a current driving module/circuit. When the current measuring system and the method thereof are used for measuring the current, the component ratio or the ideal current ratio of the current driving module/circuit would not be concerned.

A still further objective of the present invention is to provide current measuring system and a method thereof adapted for measuring a current of a current driving module/circuit. In the IC layout of the current measuring system, the current measuring system is not required to be distributed adjacent to the current driving module/circuit, or they can be configured in same or different IC chips.

For achieving the foregoing objectives and others, the present invention provides a current measuring system adapted for measuring a current flowing through a current driving module/circuit. The current measuring system includes a semiconductor component module, a resistor module, and a voltage source module. The semiconductor component module, the resistor module, and the voltage source module can be selectively or all configured in an IC manner in accordance with the practical requirement.

The semiconductor component module includes a semiconductor component. When the semiconductor component is in a conducting status, an output point voltage or a difference between an external voltage and the output point voltage, and an equivalent resistance of the current driving module/circuit are determined for determining the current flowing through the current driving module/circuit.

The voltage source module is adapted for controlling whether or not the semiconductor component of the semiconductor module is in conducting status, and is adapted for controlling components of the current driving module/circuit.

The resistor module includes at least one resistor or at least one equivalent resistor having a resistance. An absolute value of the resistance is large enough for lowering a drain/source voltage of the semiconductor component, e.g., an MOS, to an mV magnitude, when the semiconductor component is in conducting status.

The present invention further provides a method for measuring a current flowing through a current driving module/circuit in accordance with the current measuring system. The method includes the following steps. At first, an external voltage or an external current is provided to the measuring system, and the current driving module/circuit to be measured by the current measuring system. Because the absolute value of the resistance of the resistor of the resistor module of the current measuring system is large enough, so that most of the external current is directed to the current driving module/circuit. Then, an output point voltage of the current measuring system or a difference between the external voltage and the output point voltage are determined and divided by the equivalent resistance of the current driving module/circuit, thus obtaining the current flowing through the current driving module/circuit.

### BRIEF DESCRIPTION OF THE DRAWINGS

The present invention will be apparent to those skilled in the art by reading the following detailed description of preferred embodiments thereof, with reference to the attached drawings, in which:

FIG. 1 is a schematic diagram illustrating the architecture and the operation of the current measuring system of the present invention;

FIG. 2 is a flow chart illustrating the process of using the current measuring system to measure the current flowing through the current driving module/circuit according to an embodiment of the present invention;

FIG. 3 is a schematic diagram illustrating the architecture and the operation of the current measuring system according to an embodiment of the present invention;

FIG. 4 is a schematic diagram illustrating the architecture and the operation of the current measuring system according to another embodiment of the present invention;

FIG. 5 is a schematic diagram illustrating the architecture and the operation of the current measuring system according to a further embodiment of the present invention;

FIG. 6 is a flow chart illustrating the process of using the current measuring system as shown in FIG. 3 to measure the current flowing through the current driving module/circuit according to an embodiment of the present invention;

FIG. 7 is a flow chart illustrating the process of using the current measuring system as shown in FIG. 4 to measure the current flowing through the current driving module/circuit according to another embodiment of the present invention; and

FIG. 8 is a flow chart illustrating the process of using the current measuring system as shown in FIG. 5 to measure the current flowing through the current driving module/circuit according to a further embodiment of the present invention.

### DETAILED DESCRIPTION OF THE PREFERRED EMBODIMENT

The accompanying drawings are included to provide a further understanding of the invention, and are incorporated in and constitute a part of this specification. The drawing illustrates embodiments of the invention and, together with the description, serves to explain the principles of the invention.

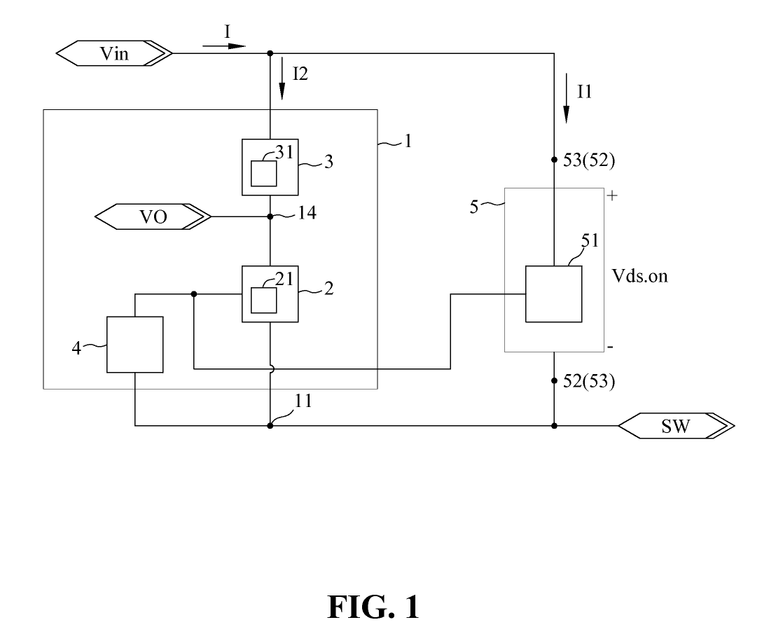

FIG. 1 is a schematic diagram illustrating the architecture and the operation of the current measuring system of the present invention. Referring to FIG. 1, the present invention provides a current measuring system 1 adapted for measuring a current flowing through a current driving module/circuit 5. The current measuring system 1 includes a semiconductor component module 2, a resistor module 3, and a voltage source module 4.

As shown in FIG. 1, an external voltage Vin is applied to the current measuring system 1 and the current driving module/circuit 5. Correspondingly, the voltage at a terminal 11 of the current measuring system 1 is SW, and the voltage at a terminal 52 or another terminal 53 of the current driving module/circuit 5 is also SW. The semiconductor component module 2 includes at least one semiconductor component 21. The resistor module 3 includes at least one resistor 31. The resistor 31 has a resistance and is preferably an equivalent resistor constituted of an MOS or a JFET. The semiconductor component module 2 and/or the resistor module 3 can be configured in an IC manner, in accordance with the practical requirement.

As shown in FIG. 1, the application of the external voltage Vin is also presented as an external current I applied to the current measuring system 1 and the current driving module/circuit 5 to be measured by the current measuring system 1. The applied external current I is then divided into a current I1 and a current I2. The current I1 flows through the current driving module/circuit 5 and the current I2 flows through the current measuring system 1. The resistance of the resistor 31 of the resistor module 3 is large enough so that most of the current I is directed to flow through the current driving module/circuit 5. As such the current I1 is much greater than the current I2.

The voltage source module 4 is adapted for controlling whether or not the semiconductor component 21 of the semiconductor module 2 is in conducting status, and is adapted for controlling a component 51 of the current driving module/circuit 5. The current driving module/circuit 5 has an equivalent resistance Rds.on (not shown in the drawings). When the current I1 flows through the current driving module/circuit 5, a voltage drop Vds.on over the equivalent resistance Rds.on occurs over the terminals 52 and 53. The voltage drop Vds.on presents as a drop between the external voltage Vin and the voltage SW. The current measuring system 1 has an output point 14 outputting an output voltage VO. The output voltage VO of the output point 14 of the current measuring system 1 is almost equivalent to the voltage SW. In such a way, the current flowing through the current driving module/circuit 5 can be measured.

When the semiconductor component 21 is controlled by the voltage source module 4 to operate in conducting status, the output voltage VO of the output point 14 of the current measuring system 1, or a difference between the external voltage Vin and the output voltage VO of the output point 14 of the current measuring system 1, as well as the equivalent resistor Rds.on of the current driving module/circuit 5 are determined, by which the current I1 flowing through the current driving module/circuit 5 can be obtained.

The semiconductor module 2 includes at least one semiconductor component 21. Preferably, the semiconductor component 21 is a metal oxide semiconductor (MOS) component, a junction field effect transistor (JFET) component, or a transistor component. The component 51 of the current driving module/circuit 5 for example can be an MOS component, or a JFET component. The voltage source module 4 is adapted to have the semiconductor component 21 and/or the component 51 to conductively work in a linear zone.

In accordance with the present invention, the semiconductor component module 2 is not required to be matched with the current driving module/circuit 5. Further, the semiconductor component 21 is not required to be matched with the component 51, and the semiconductor component 21 and the component 51 are allowed to be distributed in same or different IC chips.

The resistor module 3 includes at least one resistor 31 having a resistance. The resistance of the resistor 31 is large enough for lowering a drain/source voltage Vds of the semiconductor component 21, e.g., an MOS, to an mV magnitude, when the semiconductor component 21 is in conducting status. In such a way, the output voltage VO of the output point 14 of the current measuring system 1 differs from the voltage SW for only several mV, and therefore the output voltage VO of the output point 14 of the current measuring system 1 can be considered as equivalent with the voltage SW. Accordingly, the current flowing through the load resistor (not shown in the drawings) is almost equivalent to the current I1.

The current I1 flows through the current driving module/circuit 5 and is caused with a voltage drop over the equivalent resistance Rds.on. The output voltage VO is approximately equal to the voltage SW. Therefore, the current I1 flowing through the current driving module/circuit 5 can be determined in accordance with the output voltage VO at the output point 14 of the current measuring system 1 or the difference between the output voltage VO and the external voltage Vin, and the equivalent resistance Rds.on of the current driving module/circuit 5.

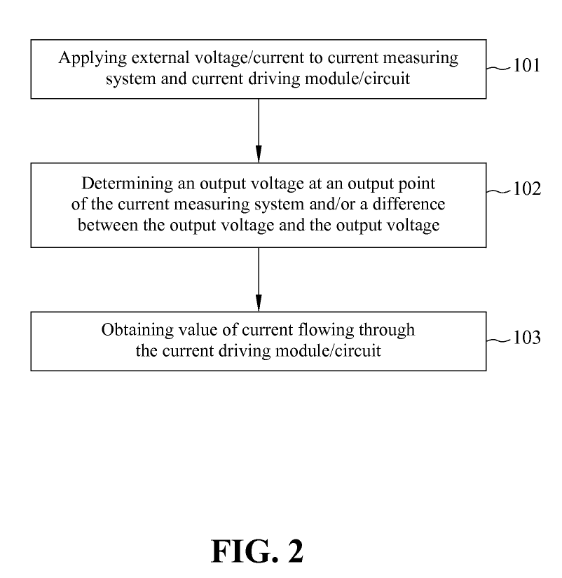

FIG. 2 is a flow chart illustrating the process of using the current measuring system to measure the current flowing through the current driving module/circuit according to an embodiment of the present invention. Referring to FIG. 2, first at step 101, an external voltage Vin is applied to the current measuring system 1, and the current driving module/circuit 5 to be measured by the current measuring system 1. The application of the external voltage Vin also provides an external current I to the current measuring system 1 and the current driving module/circuit 5 to be measured by the current measuring system 1. The applied external current I is then divided into a current I1 and a current I2. The current I1 flows through the current driving module/circuit 5 and the current I2 flows through the current measuring system 1. The resistance of the resistor 31 of the resistor module 3 is large enough so that most of the current I is directed to flow through the current driving module/circuit 5. As such the current I1 is much greater than the current I2.

The flow then enters step 102. At step 102, the output voltage VO at the output point 14 of the measuring system 1 or a difference between the output voltage VO and the external voltage Vin are determined, and then the flow enters step 103.

At step 103, the output voltage VO or the difference between the output voltage VO and the external voltage Vin, i.e., (Vin−VO), is divided by the equivalent resistance Rds.on of the current driving module/circuit, so as to obtain the current I1 flowing through the current driving module/circuit 5.

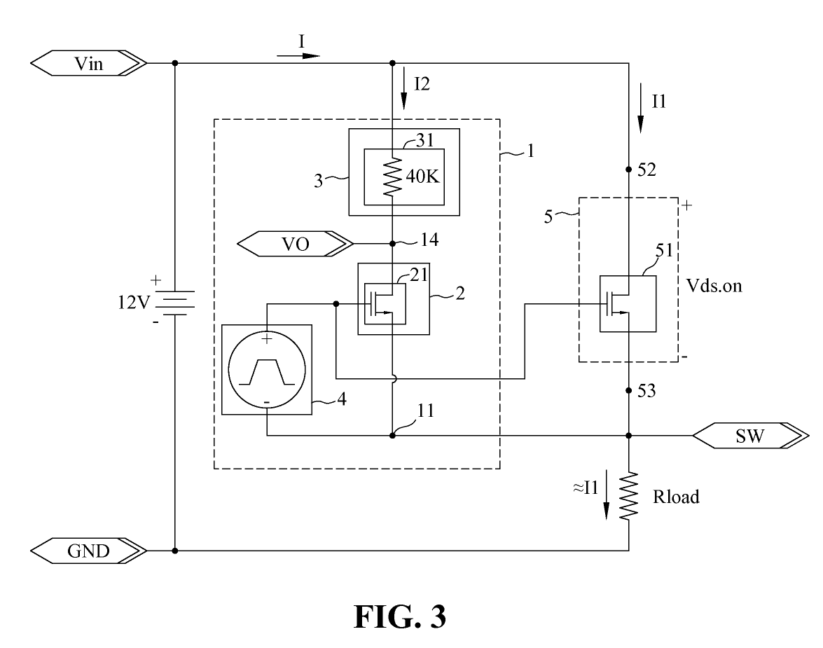

FIG. 3 is a schematic diagram illustrating the architecture and the operation of the current measuring system according to an embodiment of the present invention. Referring to FIG. 3, the present invention provides a current measuring system 1 adapted for measuring a current flowing through a current driving module/circuit 5. The current measuring system 1 includes a semiconductor component module 2, a resistor module 3, and a voltage source module 4.

As shown in FIG. 3, an external voltage Vin is applied to the current measuring system 1 and the current driving module/circuit 5. The current measuring system 1 and the current driving module/circuit 5 are respectively coupled between the external voltage Vin and a voltage SW. As shown in FIG. 3, a voltage drop between the external voltage Vin and a ground GND is 12V. A voltage at a terminal 11 of the measuring system 1 is SW. A voltage at a terminal 53 of the current driving module/circuit 5 is also SW. The semiconductor component module 2 includes a semiconductor component 21. The semiconductor component 21 is an NMOS component. The resistor module 3 includes at least one resistor 31. The resistor 31 has a resistance greater than 1 KΩ, e.g., 40 KΩ. The semiconductor component module 2 and/or the resistor module 3 can be configured in an IC manner, in accordance with the practical requirement.

As shown in FIG. 3, an external voltage Vin is applied to the current measuring system 1 and the current driving module/circuit 5. The application of the external voltage Vin is also presented as an external current I applied to the current measuring system 1 and the current driving module/circuit 5 to be measured by the current measuring system 1. The applied external current I is then divided into a current I1 and a current I2. The current I1 flows through the current driving module/circuit 5 and the current I2 flows through the current measuring system 1. The resistance of the resistor 31 of the resistor module 3 is large enough so that most of the current I is directed to flow through the current driving module/circuit 5. As such the current I1 is much greater than the current I2.

The voltage source module 4 is adapted for controlling whether or not the semiconductor component 21 of the semiconductor module 2 is in conducting status, and is adapted for controlling an NOMS component 51 of the current driving module/circuit 5. The current driving module/circuit 5 has an equivalent resistance Rds.on (not shown in the drawings). When the current I1 flows through the current driving module/circuit 5, a voltage drop Vds.on over the equivalent resistance Rds.on occurs over the terminals 52 and 53. The voltage drop Vds.on presents as a drop between the external voltage Vin and the voltage SW. The current measuring system 1 has an output point 14 outputting an output voltage VO. The output voltage VO of the output point 14 of the current measuring system 1 is almost equivalent to the voltage SW. In such a way, the current flowing through the current driving module/circuit 5 can be measured.

When the NMOS semiconductor component 21 is controlled by the voltage source module 4 to operate in conducting status, a difference between the external voltage Vin and the output voltage VO of the output point 14 of the current measuring system 1, i.e., (Vin−VO), and the equivalent resistance Rds.on of the current driving module/circuit 5 are determined, by which the current I1 flowing through the current driving module/circuit 5 can be obtained.

The semiconductor module 2 includes at least one semiconductor component 21. Preferably, the semiconductor component 21 is an NMOS component. The component 51 of the current driving module/circuit 5 is also an NOMS component. The voltage source module 4 is adapted to have the semiconductor component 21 and/or the component 51 to conductively work in a linear zone.

In accordance with the present invention, the semiconductor component module 2 is not required to be matched with the current driving module/circuit 5. Further, the semiconductor component 21 is not required to be matched with the component 51, and the semiconductor component 21 and the component 51 are allowed to be distributed in same or different IC chips.

The resistor module 3 includes at least one resistor 31 having a resistance. In the current embodiment, the resistance of the resistor 31 is 40 KΩ, so that the resistance of the resistor 31 is large enough for lowering a drain/source voltage Vds of the NMOS semiconductor component 21 to several mV, when the semiconductor component 21 is in conducting status. In such a way, the output voltage VO of the output point 14 of the current measuring system 1 differs from the voltage SW for only several mV, and therefore the output voltage VO of the output point 14 of the current measuring system 1 can be considered as equivalent with the voltage SW. Accordingly, the current flowing through the load resistor (not shown in the drawings) is almost equivalent to the current I1.

The current I1 flows through the current driving module/circuit 5 and is caused with a voltage drop over the equivalent resistance Rds.on. The output voltage VO is approximately equal to the voltage SW. The equivalent resistance Rds.on of the current driving module/circuit 5 is a known value. Therefore, the current I1 flowing through the current driving module/circuit 5 can be determined in accordance with the difference between the output voltage VO and the external voltage Vin, i.e., (Vin−VO), and the equivalent resistance Rds.on of the current driving module/circuit 5. Specifically, the current I1 flowing through the current driving module/circuit 5 is [(Vin−VO)/Rds.on]. In other words, the current I1 flowing through the current driving module/circuit 5 can be obtained by dividing the voltage drop (Vin−VO) over the two terminals of the resistor module 3 with the equivalent resistance Rds.on of the current driving module/circuit 5.

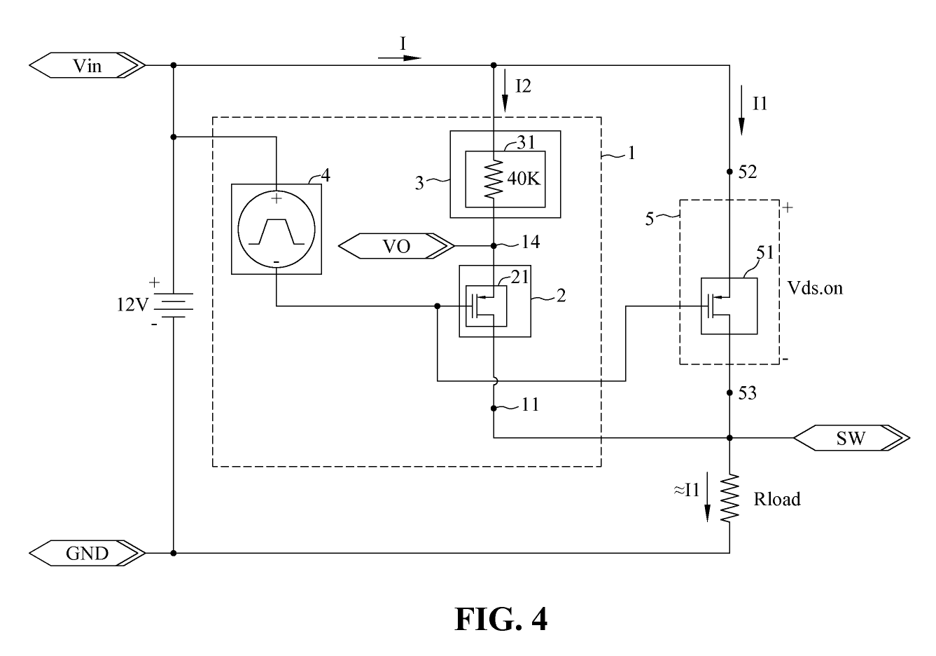

FIG. 4 is a schematic diagram illustrating the architecture and the operation of the current measuring system according to another embodiment of the present invention. Referring to FIG. 4, the present invention provides a current measuring system 1 adapted for measuring a current flowing through a current driving module/circuit 5. The current measuring system 1 includes a semiconductor component module 2, a resistor module 3, and a voltage source module 4.

As shown in FIG. 4, in the current embodiment, an external voltage Vin is applied to the current measuring system 1 and the current driving module/circuit 5. The current measuring system 1 and the current driving module/circuit 5 are respectively coupled between the external voltage Vin and a voltage SW. As shown in FIG. 4, a voltage drop between the external voltage Vin and a ground GND is 12V. The voltage source module 4 has a positive electrode electrically connected with a positive electrode of the 12V voltage drop. A voltage at a terminal 11 of the measuring system 1 is SW. A voltage at a terminal 53 of the current driving module/circuit 5 is also SW. The semiconductor component module 2 includes at least one semiconductor component 21. The semiconductor component 21 is a PMOS component. The resistor module 3 includes at least one resistor 31. The resistor 31 has a resistance or an equivalent resistance consisting of MOS or JFET component. The resistance or the equivalent resistance of the resistor 31 is greater than 1 KΩ, e.g., 40 KΩ. The semiconductor component module 2 and/or the resistor module 3 can be configured in an IC manner, in accordance with the practical requirement.

As shown in FIG. 4, an external voltage Vin is applied to the current measuring system 1 and the current driving module/circuit 5. The application of the external voltage Vin is also presented as an external current I applied to the current measuring system 1 and the current driving module/circuit 5 to be measured by the current measuring system 1. The applied external current I is then divided into a current I1 and a current I2. The current I1 flows through the current driving module/circuit 5 and the current I2 flows through the current measuring system 1. The resistance of the resistor 31 of the resistor module 3 is 40 KΩwhich is large enough so that most of the current I is directed to flow through the current driving module/circuit 5.

The voltage source module 4 is adapted for controlling whether or not the PMOS semiconductor component 21 of the semiconductor module 2 is in conducting status, and is adapted for controlling a POMS component 51 of the current driving module/circuit 5. As shown in FIG. 4, the current driving module/circuit 5 has an equivalent resistance Rds.on (not shown in the drawings). When the current I1 flows through the current driving module/circuit 5, a voltage drop Vds.on over the equivalent resistance Rds.on occurs over the terminals 52 and 53. The voltage drop Vds.on presents as a drop between the external voltage Vin and the voltage SW. The current measuring system 1 has an output point 14 outputting an output voltage VO. The output voltage VO of the output point 14 of the current measuring system 1 is almost equivalent to the voltage SW. In such a way, the current flowing through the current driving module/circuit 5 can be measured.

When the PMOS semiconductor component 21 is controlled by the voltage source module 4 to operate in conducting status, a difference between the external voltage Vin and the output voltage VO of the output point 14 of the current measuring system 1, i.e., (Vin−VO), and the equivalent resistance Rds.on of the current driving module/circuit 5 are determined, by which the current I1 flowing through the current driving module/circuit 5 can be obtained.

The semiconductor module 2 includes at least one semiconductor component 21. Preferably, the semiconductor component 21 is a PMOS component. The component 51 of the current driving module/circuit 5 is also a POMS component. The voltage source module 4 is adapted to have the semiconductor component 21 and/or the component 51 to conductively work in a linear zone.

In accordance with the present invention, the semiconductor component module 2 is not required to be matched with the current driving module/circuit 5. Further, the semiconductor component 21 is not required to be matched with the component 51, and the semiconductor component 21 and the component 51 are allowed to be distributed in same or different IC chips.

The resistor module 3 includes at least one resistor 31 having a resistance. In the current embodiment, the resistance of the resistor 31 is 40 KΩ, so that the resistance of the resistor 31 is large enough for lowering a drain/source voltage Vds of the PMOS semiconductor component 21 to several mV, when the PMOS semiconductor component 21 is in conducting status. In such a way, the output voltage VO of the output point 14 of the current measuring system 1 differs from the voltage SW for only several mV, and therefore the output voltage VO of the output point 14 of the current measuring system 1 can be considered as equivalent with the voltage SW. Accordingly, the current flowing through the load resistor (not shown in the drawings) is almost equivalent to the current I1.

The current I1 flows through the current driving module/circuit 5 and is caused with a voltage drop over the equivalent resistance Rds.on. The output voltage VO is approximately equal to the voltage SW. The equivalent resistance Rds.on of the current driving module/circuit 5 is a known value. Therefore, the current I1 flowing through the current driving module/circuit 5 can be determined in accordance with the difference between the output voltage VO and the external voltage Vin, i.e., (Vin−VO), and the equivalent resistance Rds.on of the current driving module/circuit 5. Specifically, the current I1 flowing through the current driving module/circuit 5 is [(Vin−VO)/Rds.on]. In other words, the current I1 flowing through the current driving module/circuit 5 can be obtained by dividing the voltage drop (Vin−VO) over the two terminals of the resistor module 3 with the equivalent resistance Rds.on of the current driving module/circuit 5.

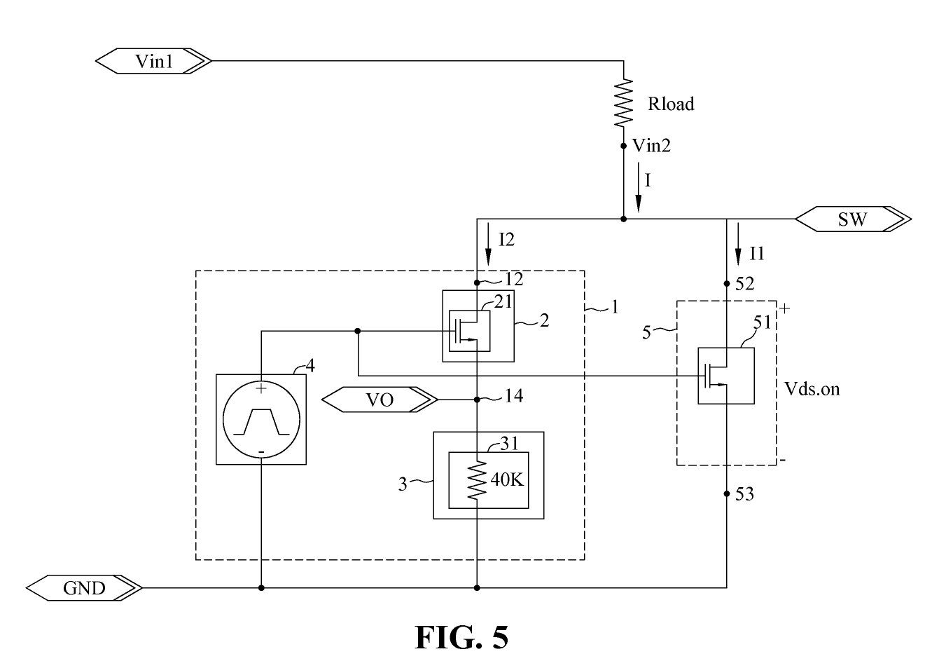

FIG. 5 is a schematic diagram illustrating the architecture and the operation of the current measuring system according to a further embodiment of the present invention. Referring to FIG. 5, the present invention provides a current measuring system 1 adapted for measuring a current flowing through a current driving module/circuit 5. The current measuring system 1 includes a semiconductor component module 2, a resistor module 3, and a voltage source module 4.

As shown in FIG. 5, in the current embodiment, a first external voltage Vin1 is provided to a resistor Rload, and after the resistor Rload, the first external voltage Vin1 drops to a second external voltage Vin2. The second external voltage Vin2 is applied to the current measuring system 1 and the current driving module/circuit 5. The current measuring system 1 and the current driving module/circuit 5 are respectively coupled between the second external voltage Vin2 and a ground GND. As shown in FIG. 5, the voltage source module 4 includes a negative electrode electrically coupled to the ground GND. A voltage at a terminal 12 of the measuring system 1 is SW. A voltage at a terminal 52 of the current driving module/circuit 5 is also SW. The semiconductor component module 2 includes at least one semiconductor component 21. The semiconductor component 21 is an NMOS component. The resistor module 3 includes at least one resistor 31. The resistor 31 has a resistance or an equivalent resistance consisting of MOS or JFET component. The resistance or the equivalent resistance of the resistor 31 is greater than 1 KΩ, e.g., 40 KΩ. The semiconductor component module 2 and/or the resistor module 3 can be configured in an IC manner, in accordance with the practical requirement.

As shown in FIG. 5, the second external voltage Vin2 is applied to the current measuring system 1 and the current driving module/circuit 5. The application of the second external voltage Vin2 is also presented as an external current I applied to the current measuring system 1 and the current driving module/circuit 5 to be measured by the current measuring system 1. The applied external current I is then divided into a current I1 and a current I2. The current I1 flows through the current driving module/circuit 5 and the current I2 flows through the current measuring system 1. The resistance of the resistor 31 of the resistor module 3 is 40 KΩwhich is large enough so that most of the current I is directed to flow through the current driving module/circuit 5.

The voltage source module 4 is adapted for controlling whether or not the NMOS semiconductor component 21 of the semiconductor module 2 is in conducting status, and is adapted for controlling an NOMS component 51 of the current driving module/circuit 5. As shown in FIG. 5, the current driving module/circuit 5 has an equivalent resistance Rds.on (not shown in the drawings). When the current I1 flows through the current driving module/circuit 5, a voltage drop Vds.on over the equivalent resistance Rds.on occurs over the terminals 52 and 53. The voltage drop Vds.on presents as a drop between the voltage SW and the ground GND. The current measuring system 1 has an output point 14 outputting an output voltage VO. The output voltage VO of the output point 14 of the current measuring system 1 is almost equivalent to the voltage SW. In such a way, the current flowing through the current driving module/circuit 5 can be measured.

When the NMOS semiconductor component 21 is controlled by the voltage source module 4 to operate in conducting status, the output voltage VO of the output point 14 of the current measuring system 1 and the equivalent resistance Rds.on of the current driving module/circuit 5 are determined, by which the current I1 flowing through the current driving module/circuit 5 can be obtained.

The semiconductor module 2 includes at least one semiconductor component 21. Preferably, the semiconductor component 21 is an NMOS component. The component 51 of the current driving module/circuit 5 is also an NOMS component. The voltage source module 4 is adapted to have the semiconductor component 21 and/or the component 51 to conductively work in a linear zone.

In accordance with the present invention, the semiconductor component module 2 is not required to be matched with the current driving module/circuit 5. Further, the semiconductor component 21 is not required to be matched with the component 51, and the semiconductor component 21 and the component 51 are allowed to be distributed in same or different IC chips.

The resistor module 3 includes at least one resistor 31 having a resistance. In the current embodiment, the resistance of the resistor 31 is 40 KΩ, so that the resistance of the resistor 31 is large enough for lowering a drain/source voltage Vds of the NMOS semiconductor component 21 to several mV, when the NMOS semiconductor component 21 is in conducting status. In such a way, the output voltage VO of the output point 14 of the current measuring system 1 differs from the voltage SW for only several mV, and therefore the output voltage VO of the output point 14 of the current measuring system 1 can be considered as equivalent with the voltage SW. Accordingly, the current flowing through the load resistor (not shown in the drawings) is almost equivalent to the current I1.

The current I1 flows through the current driving module/circuit 5 and is caused with a voltage drop over the equivalent resistance Rds.on. The output voltage VO is approximately equal to the voltage SW. The equivalent resistance Rds.on of the current driving module/circuit 5 is a known value. Therefore, the current I1 flowing through the current driving module/circuit 5 can be determined in accordance with the output voltage VO and the equivalent resistance Rds.on of the current driving module/circuit 5. Specifically, the current I1 flowing through the current driving module/circuit 5 is [VO/Rds.on]. In other words, the current I1 flowing through the current driving module/circuit 5 can be obtained by dividing the voltage drop VO over the two terminals of the resistor module 3 with the equivalent resistance Rds.on of the current driving module/circuit 5.

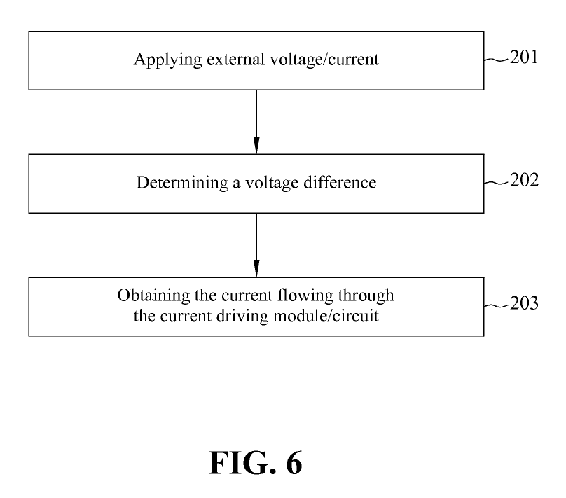

FIG. 6 is a flow chart illustrating the process of using the current measuring system as shown in FIG. 3 to measure the current flowing through the current driving module/circuit according to an embodiment of the present invention. Referring to FIGS. 6 and 3, first at step 201, an external voltage Vin is applied to the current measuring system 1, and the current driving module/circuit 5 to be measured by the current measuring system 1. The application of the external voltage Vin also provides an external current I to the current measuring system 1 and the current driving module/circuit 5 to be measured by the current measuring system 1. The applied external current I is divided into a current I1 and a current I2. The current I1 flows through the current driving module/circuit 5 and the current I2 flows through the current measuring system 1. The semiconductor component module 2 includes a semiconductor component 21. The semiconductor component 21 is an NMOS component. The current driving module/circuit 5 includes a component 51. The component 51 of the current driving module/circuit 5 is also an NMOS component. The resistor module 3 includes at least one resistor 31. The resistor 31 has a resistance greater than 1 KΩ, e.g., 40 KΩ. As such, the resistance of the resistor 31 of the resistor module 3 is large enough so that most of the current I is directed to flow through the current driving module/circuit 5.

The flow then enters step 202. At step 202, a difference between the output voltage VO at the output point 14 of the measuring system 1 and the external voltage Vin, i.e., (Vin−VO), is determined, and then the flow enters step 203.

At step 203, the difference between the output voltage VO and the external voltage Vin, i.e., (Vin−VO), is divided by the equivalent resistance Rds.on of the current driving module/circuit, so as to obtain the current I1 flowing through the current driving module/circuit 5 according to the equation of I1=[(Vin−VO)/Rds.on].

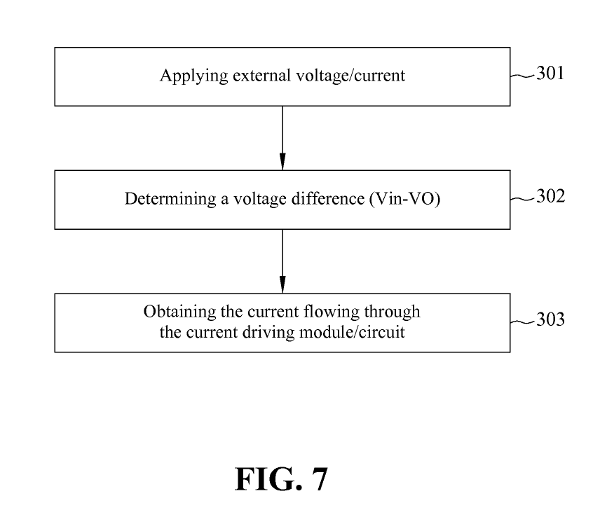

FIG. 7 is a flow chart illustrating the process of using the current measuring system as shown in FIG. 4 to measure the current flowing through the current driving module/circuit according to another embodiment of the present invention. Referring to FIGS. 7 and 4, first at step 301, an external voltage Vin is applied to the current measuring system 1, and the current driving module/circuit 5 to be measured by the current measuring system 1. The application of the external voltage Vin also provides an external current I to the current measuring system 1 and the current driving module/circuit 5 to be measured by the current measuring system 1. The applied external current I is divided into a current I1 and a current I2. The current I1 flows through the current driving module/circuit 5 and the current I2 flows through the current measuring system 1. The semiconductor component module 2 includes a semiconductor component 21. The semiconductor component 21 is a PMOS component. The current driving module/circuit 5 includes a component 51. The component 51 of the current driving module/circuit 5 is also a PMOS component. The resistor module 3 includes at least one resistor 31. The resistor 31 has a 40 KΩresistance. As such, the resistance of the resistor 31 of the resistor module 3 is large enough so that most of the current I is directed to flow through the current driving module/circuit 5.

The flow then enters step 302. At step 302, a difference between the output voltage VO at the output point 14 of the measuring system 1 and the external voltage Vin, i.e., (Vin−VO), is determined, and then the flow enters step 303.

At step 303, the difference between the output voltage VO and the external voltage Vin, i.e., (Vin−VO), is divided by the equivalent resistance Rds.on of the current driving module/circuit, so as to obtain the current I1 flowing through the current driving module/circuit 5 according to the equation of I1=[(Vin−VO)/Rds.on].

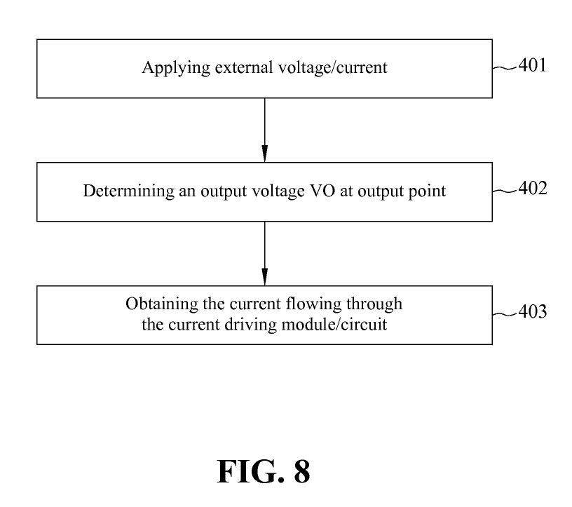

FIG. 8 is a flow chart illustrating the process of using the current measuring system as shown in FIG. 5 to measure the current flowing through the current driving module/circuit according to a further embodiment of the present invention. Referring to FIGS. 8 and 5, first at step 401, an external voltage Vin is applied to the current measuring system 1, and the current driving module/circuit 5 to be measured by the current measuring system 1. The application of the external voltage Vin also provides an external current I to the current measuring system 1 and the current driving module/circuit 5 to be measured by the current measuring system 1. The applied external current I is divided into a current I1 and a current I2. The current I1 flows through the current driving module/circuit 5 and the current I2 flows through the current measuring system 1. The semiconductor component module 2 includes a semiconductor component 21. The semiconductor component 21 is an NMOS component. The current driving module/circuit 5 includes a component 51. The component 51 of the current driving module/circuit 5 is also an NMOS component. The resistor module 3 includes at least one resistor 31. The resistor 31 has a 40 KΩresistance. As such, the resistance of the resistor 31 of the resistor module 3 is large enough so that most of the current I is directed to flow through the current driving module/circuit 5.

The flow then enters step 402. At step 202, an output voltage VO at the output point 14 of the measuring system 1 is determined, and then the flow enters step 403.

At step 403, the output voltage VO is divided by the equivalent resistance Rds.on of the current driving module/circuit, so as to obtain the current I1 flowing through the current driving module/circuit 5 according to the equation of I1=[VO/Rds.on].

In accordance with the foregoing embodiments, although the resistance of the resistor 31 of the resistor module 3 is exemplified as 40 KΩ, the resistance of the resistor 31 is required to be large enough for lowering the drain/source voltage Vds of the NMOS semiconductor component 21 to several mV, but not restricted to be 40 KΩ. The resistor 31 can be alternatively an equivalent resistor consisting of MOS or JFET. Further, the semiconductor component module 2 can also be realized in other manners, and is not restricted as only including a semiconductor component as discussed above. Any other modifications or alternations would be convenient to understand by referring to the foregoing discussion, and are not to be iterated hereby.

In summary, the present invention provides a current measuring system and a method thereof adapted for measuring a current of a current driving module/circuit. When the current measuring system and the method thereof are used for measuring the current, the current measuring system is not required to be well matched with the current driving module/circuit, and the component ratio or the ideal current ratio of the current driving module/circuit would not be concerned. Further, in the IC layout of the current measuring system, the current measuring system is not required to be distributed adjacent to the current driving module/circuit, or they can be configured in same or different IC chips. When the current measuring system and the method thereof are used for measuring the current flowing through the current driving module/circuit, the current can be measured by determining an output point voltage or a difference between an external voltage and the output point voltage.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A current measuring method of using a current measuring system for measuring a current flowing through a current driving module/circuit, comprising:
applying an external voltage to the current measuring system and the current driving module/circuit to be measured by the current measuring system, wherein the application of the external voltage is also presented as an external current provided to the current measuring system and the current driving module/circuit;
determining a difference between the external voltage and a voltage at an output point of the current measuring system; and
dividing the difference with an equivalent resistance of the current driving module/circuit to obtain the current flowing through the current driving module/circuit.

2. A current measuring method of using a current measuring system for measuring a current flowing through a current driving module/circuit, comprising:
applying an external voltage to the current measuring system and the current driving module/circuit to be measured by the current measuring system, wherein the application of the external voltage is also presented as an external current provided to the current measuring system and the current driving module/circuit;
determining a voltage at an output point of the current measuring system; and
dividing the voltage at the output point of the current measuring system with an equivalent resistance of the current driving module/circuit to obtain the current flowing through the current driving module/circuit.

3. The current measuring method as claimed in claim 2, wherein the current measuring system is not required to be matched with the current driving module/circuit.

4. The current measuring method as claimed in claim 2, wherein the current measuring system and the current driving module/circuit are configured by same or different IC processes.

5. The current measuring method as claimed in claim 2, wherein the current measuring system and the current driving module/circuit are configured in same or different IC chips.

6. A current measuring method of using a current measuring system for measuring a current flowing through a current driving module/circuit, the current measuring system comprising a semiconductor component module, a resistor module, and a voltage source module, the current measuring method comprising:
applying an external voltage to the current measuring system and the current driving module/circuit to be measured by the current measuring system, wherein the application of the external voltage is also presented as an external current provided to the current measuring system and the current driving module/circuit, wherein the resistor module comprises a resistor having a resistance large enough for directing most of the external current to flow through the current driving module/circuit;
using the voltage source module to control a semiconductor component of the semiconductor component module and a component of the current driving module/circuit to work in conducting status, and determining a difference between the external voltage and a voltage at an output point of the current measuring system; and
dividing the difference with an equivalent resistance of the current driving module/circuit to obtain the current flowing through the current driving module/circuit.

7. A current measuring method of using a current measuring system for measuring a current flowing through a current driving module/circuit, the current measuring system comprising a semiconductor component module, a resistor module, and a voltage source module, the current measuring method comprising:
applying an external voltage to the current measuring system and the current driving module/circuit to be measured by the current measuring system, wherein the application of the external voltage is also presented as an external current provided to the current measuring system and the current driving module/circuit, wherein the resistor module comprises a resistor for directing most of the external current to flow through the current driving module/circuit;
using the voltage source module to control a semiconductor component of the semiconductor component module and a component of the current driving module/circuit to work in conducting status, and determining a voltage at an output point of the current measuring system; and
dividing the voltage at the output point of the current measuring system with an equivalent resistance of the current driving module/circuit to obtain the current flowing through the current driving module/circuit.

8. The current measuring method as claimed in claim 7, wherein the current measuring system is not required to be matched with the current driving module/circuit.

9. The current measuring method as claimed in claim 7, wherein the current measuring system and the current driving module/circuit are configured by same or different IC processes.

10. The current measuring method as claimed in claim 7, wherein the current measuring system and the current driving module/circuit are configured in same or different IC chips.

11. The current measuring method as claimed in claim 7, wherein the semiconductor component is an MOS component.

12. The current measuring method as claimed in claim 7, wherein the component of the current driving module/circuit is an MOS component.

13. The current measuring method as claimed in claim 7, wherein the resistance of the resistor of the resistor module is greater than 1 KΩ.

14. The current measuring method as claimed in claim 7, wherein the resistor of the resistor module is an equivalent resistor consisting of an MOS or a JFET component.

15. A current measuring system, adapted for measuring a current flowing through a current driving module/circuit, comprising:
a resistor module comprising a resistor having a large absolute value resistance;
a semiconductor component module, comprising a semiconductor component, wherein when the semiconductor component is in conducting status, the current flowing through the current driving module/circuit is determined by dividing a voltage drop over two terminals of the resistor module with an equivalent resistance of the current driving module/circuit; and
a voltage source module, adapted for controlling whether or not the semiconductor component is in conducting status, and adapted for controlling the current driving module/circuit.

16. A current measuring system, adapted for measuring a current flowing through a current driving module/circuit, wherein an external voltage is applied to the current measuring system and the current driving module/circuit, and the application of the external voltage is also presented as an external current provided to the current measuring system and the current driving module/circuit, the current measuring system comprising:
a resistor module comprising a resistor, wherein the resistor has an absolute value of resistance large enough for directing most of the external current to flow through the current driving module/circuit;
a semiconductor component module, comprising a semiconductor component, wherein when the semiconductor component and a corresponding component of the current driving module/circuit are in conducting status, the current flowing through the current driving module/circuit is determined by dividing a voltage drop over two terminals of the resistor module with an equivalent resistance of the current driving module/circuit; and
a voltage source module, adapted for controlling whether or not the semiconductor component and the corresponding component of the current driving module/circuit are in conducting status.

17. The current measuring system as claimed in claim 16, wherein the current measuring system is not required to be matched with the current driving module/circuit.

18. The current measuring system as claimed in claim 16, wherein the current measuring system and the current driving module/circuit are configured by same or different IC processes.

19. The current measuring system as claimed in claim 16, wherein the current measuring system and the current driving module/circuit are configured in same or different IC chips.

20. The current measuring system as claimed in claim 16, wherein the semiconductor component is an MOS component.

21. The current measuring system as claimed in claim 16, wherein the resistance of the resistor of the resistor module is greater than 1 KΩ.

22. The current measuring system as claimed in claim 16, wherein the resistor of the resistor module is an equivalent resistor consisting of an MOS or a JFET component.

23. The current measuring system as claimed in claim 16, wherein semiconductor component is a JFET component.

24. The current measuring system as claimed in claim 16, wherein the semiconductor component is a transistor component.

25. The current measuring system as claimed in claim 16, wherein the semiconductor component and the resistor are configured in an IC manner.
